(19) United States
(12) Patent Application Publication
(10) Pub. No.: US 2009/0297300 A1
(43) Pub. Date: Dec. 3, 2009

(54) APPARATUS AND METHOD FOR TRANSFERRING A PLURALITY OF CHIPS FROM A WAFER TO A SUB STRATE

(75) Inventor: Volker Brod, Bad Abbach (DE)

Correspondence Address: BLACK LOWE & GRAHAM, PLLC, 701 FIFTH AVENUE, SUITE 4800, SEATTLE, WA, 98104, US

(73) Assignee: MUEHLBAUER AG, Roding (DE)

(21) Appl. No.: 12/161,242

(22) PCT Filed: Dec. 13, 2006
(86) PCT No.: PCT/EP2006/069658

§ 371 Date: Jul. 21, 2009

(30) Foreign Application Priority Data
Jan. 17, 2006 (DE) 10 2006 002 367.6

(51) Int. Cl. H01L 21/68

(52) U.S. Cl. 414/222.01

(57) ABSTRACT

An apparatus and a method for transferring a plurality of chips from a wafer onto a substrate, in particular a web, wherein at least one first disc or at least on first roll is disposed for successively picking up the chips on the outer perimeter thereof by means of a rotational movement of the first disc or the first roll.

The invention relates to an apparatus and a method for transferring a plurality of chips from a wafer to a substrate according to the pre-characterising clauses of claims 1 and 14.

During the production of wafers, in particular silicon wafers having a multiplicity of chips positioned in one plane, the wafers are separated to chip size. The individual chips are then still adhering with one of their surfaces to a common substrate film and will, as a rule, have electrical terminals in the form of bumps on the opposite free surface. These first chip surfaces provided with bumps need to be turned over by means of a chip-flip process with a view to subsequently depositing the chip onto a web or a card, on which further contact terminals are disposed for contacting the chip with further devices such as antennae.

Such flip-chip processes are time-consuming, since each chip has to be picked up from the wafer, for example by means of a pipette-type device for creating a vacuum, and subsequently be turned over by 180°, in order to turn the contact terminals from top to bottom, whereupon the chip has to be transferred and the chip geometry to be measured relative to a loading axis, on which a web including a multiplicity of antennae or cards is disposed. To this end, the chip geometry has to be measured with a view to subsequently depositing the chip in an appropriate contacting position in relation to contact terminals already disposed on the web or the substrate material.

In order to achieve the required mounting precision of the contact terminals disposed on the web or the substrate material, the geometry of the contact surfaces will be measured prior to the contacting process and the connecting process (bonding process), in order to achieve a precise deposition of the chip at the bonding position of the web or the substrate material by means of the coordinates (x, y and phi) of the chip, which were measured in the same way.

In order to carry out such a sequential concatenation of several steps involved in the bonding process, parallelisation by means of arranged multi-axis systems is oftentimes sought for. By this means, the throughput rate of the entire apparatus may be increased, even where labour-intensive bonding process operations are involved. However, such parallelisation requires as a rule long transfer routes and the use of several multi-axis systems. This leads to increased manufacturing and operating costs.

Consequently, the present invention is based on the object of providing an apparatus and a method for transferring a plurality of chips from a wafer onto a substrate, in particular a web, which allows the chip-mounting times to be reduced, whilst long transfer routes are avoided.

This object is achieved on the part of the apparatus by means of the features of claim 1 and on the part of the method by means of the features of claim 14.

An essential point of the invention is that in the apparatus for transferring a plurality of chips from a wafer onto a web, at least one first disc or at least one first roll for successively receiving the chips on its outer perimeter by means of a rotational movement of the first disc or the first roll is provided. The provision of such a disc allows a continuous or a discontinuous—with brief stops—reception of the chips, which are disposed within one plane in the wafers, and a simultaneous deposition of the chips present on the side of the first disc or the first roll, which is opposite the wafer side, onto a second disc or a linear element having a linearly formed surface. Thus, a substantial time saving is achieved between the actual picking process corresponding to the removal operation from the wafer, and the depositing process of the chip on the web, which may include antennae, for example for manufacturing smart label inlays, due to the use of a rotatory method. This enables the throughput rate of the entire chip-mounting apparatus to be increased, whilst reducing the long transfer routes which were previously necessary, whereby a faster production of chip-including transponders, cards etc. per time unit is achieved.

Preferably at least one second disc or at least one second roll will be used to successively receive the chips provided on the outer perimeter of the first disk/roll by means of a rotational movement on the outer perimeter of the second disk/roll, in order to thereby achieve a flip process. Thus, advantageously every chip will be quickly and simply flipped over in a continuous process, without there being any manufacturing and cost-intensive structures necessary for carrying out a 180° turn of the chip.

By means of the second disc or the second roll, the chips may be deposited successively onto the web either directly in the area in which the antenna connection surfaces of the antennae already provided on the web are located, or indirectly by laterally shifting the second disc or several disks in an axial direction relative to a radial plane of the first disc in such a way that a web laterally spaced on the second disc relative to the first disc will be loaded upon a shifting movement.

Ideally, at least two second disks/rolls are shifted to the left and to the right on the left hand side and the right hand side opposite the radial planes of the first disc and will be alternately disposed on the second disc upstream of the first disc for receiving the individual chips from the first disk. This enables a quick transfer of the chips from the first disc onto the substrate to be loaded, such as webs.

According to a preferred embodiment, each chip will be retained on the first disk/the first roll by its first surface by means of a first element acting with vacuum pressure. On the second disk/the second roll, each chip will be retained by its second surface, which is positioned opposite the first surface, by means of a second element acting with vacuum pressure.

The second elements acting with vacuum pressure are arranged in such a way that they can be shifted in the radial direction of the disk/roll and can be pressurised, if necessary, in order to exert pressure during deposition of the chips on the web whilst establishing contact between the chip and the contact terminals of the antennae on the chips.

Additionally, the first and second elements acting with vacuum pressure are supported to rotate about an axis extending in the radial direction of the disk/roll, in order to achieve an optimal alignment of the chips adhering to these elements also with respect to their rotational position.

By means of the pressurisable second elements acting with vacuum pressure on the second disk/roll, for example so-called nanobond technology may be used, which creates a permanent contact connection by simply pressing the chips onto the contact surfaces of the antennae. This is achieved by forming the contact surfaces provided on the antenna and on the chip as self-conducting minute hairs and self-conducting minute eyelets, which form e.g. the antenna contact surfaces. As a result, the contact surfaces are formed with an area as large as possible.

Thus, during mounting of the chips, these chips are mounted by simply positioning the antenna contact terminals and pressing them on and at the same time an electrical contact will be established with these contact terminals. As a result, the conductive, mostly anisotropic adhesives which have been used to date for manufacturing a permanent contact between the antenna contact surfaces and the contact surfaces of the chip of the chip module, which need a curing time of several seconds, are no longer necessary. Such a curing time would in turn reduce the throughput rate of the entire apparatus. Thus, by means of the combination of nanobond technology in connection with a rotational removal of the individual chips from the wafer, an apparatus with a high throughput rate will be obtained.

Principally, for enhancing the throughput rate of the entire apparatus as well as for increasing the amount of chips during a chip mounting process within a given time, a plurality of first disks or first rolls may be guided in parallel in such a way that they may be driven independently from each other and may be loaded with chips. Also, several second disks/second rolls may be used as flip-chip pressure disks or flip-chip pressure rolls for carrying out the flip process.

As an alternative to the second disks/second rolls, at least one linear element may be used which includes on a usually linear surface a plurality of third elements acting with vacuum pressure and arranged in rows, for successively receiving the chips provided on the outer perimeter of the first disk/roll on its second surface by means of a shifting movement in the longitudinal direction of the linear element.

The linear element, which is provided e.g. as a beam-like linear transport element, may, in order to carry out a linear flip-chip pressure operation, deposit either several chips suspended on the third elements in parallel on the web or may deposit the chips individually one after another.

A parallel deposition of the chips is preferred, provided the tolerances of the contact surfaces of the chips and the antennae are large. To this end, discontinuous loading may be advantageous, i.e. stopping the web for a short time in order to deposit the individual chips on the surfaces of the antenna contact terminals.

By contrast, if at least one second pressure disc or one second pressure roll is used, a continuously moving web tape will preferably be used, since this enables a continuous deposition of the individual chips on the web due to the rotational movement. Alternatively, here too a discontinuous deposition of the chips may be carried out in such a way that the web is briefly stopped for each chip.

The third elements acting with vacuum pressure are again formed so that they may be shifted and pressurised, this being carried out in a vertical direction to the longitudinal direction of the linear element. Also, the third elements acting with vacuum pressure may be twisted about an axis extending vertically to the longitudinal direction of the linear element, in order to obtain an optimal alignment of the chip relative to the contact terminals of the antennae on the web.

A method for successively transferring a plurality of chips from the wafer onto the web will advantageously use a rotational movement of the first disk/the first roll in order to receive chips from at least one of the first disks or at least one of the first rolls on its outer perimeter and to transfer them subsequently from the first disc onto the outer perimeter of a second disk/a second roll or the surface of at least one linear element. To this end, the elements acting with vacuum pressure are disposed on the outer perimeter of the first disk, the second disc and the surface of the linear element as close to each other as possible, whilst the distances between the first and second elements on the first and second disc may be different from each other, in order to achieve thereby, if necessary, a desired speed matching for the deposition process of the chips on the substrate material, such as a web or cards.

Provided two or more second disks or two or more second rolls are used, these are alternately pushed from the first roll to and from the transfer position, in order to subsequently carry out the loading of the antennae disposed on the web with the chips.

All of the elements acting with vacuum pressure will engage in the contact-element-free areas of the surfaces of the chips in order to avoid damaging the contact surfaces. This may be carried out for example by providing that a pipette-type vacuum device contacts the surface of the chip between two contact surfaces.

Any further embodiments will become evident from the dependent claims.

Advantages and expedient features will be evident from the following description in connection with the drawings, wherein:

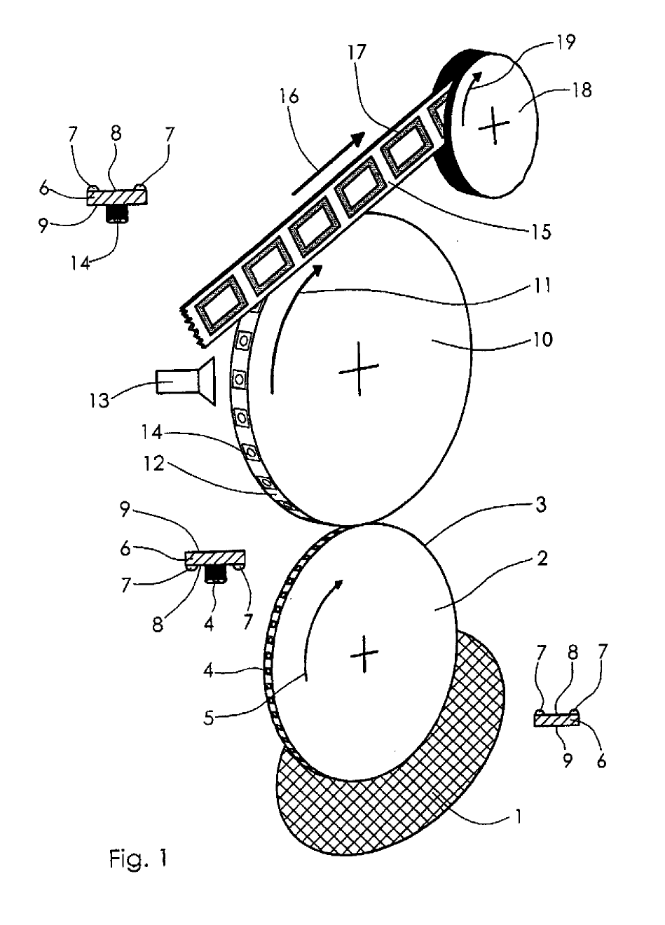

FIG. 1 shows a schematic view of a first embodiment of the apparatus according to the invention;

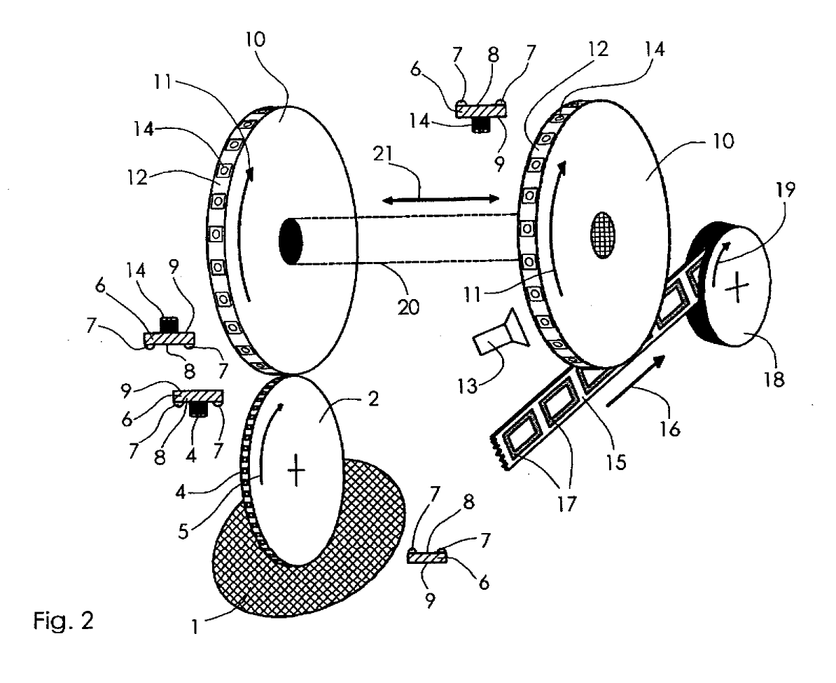

FIG. 2 shows a schematic view of a second embodiment of the apparatus according to the invention;

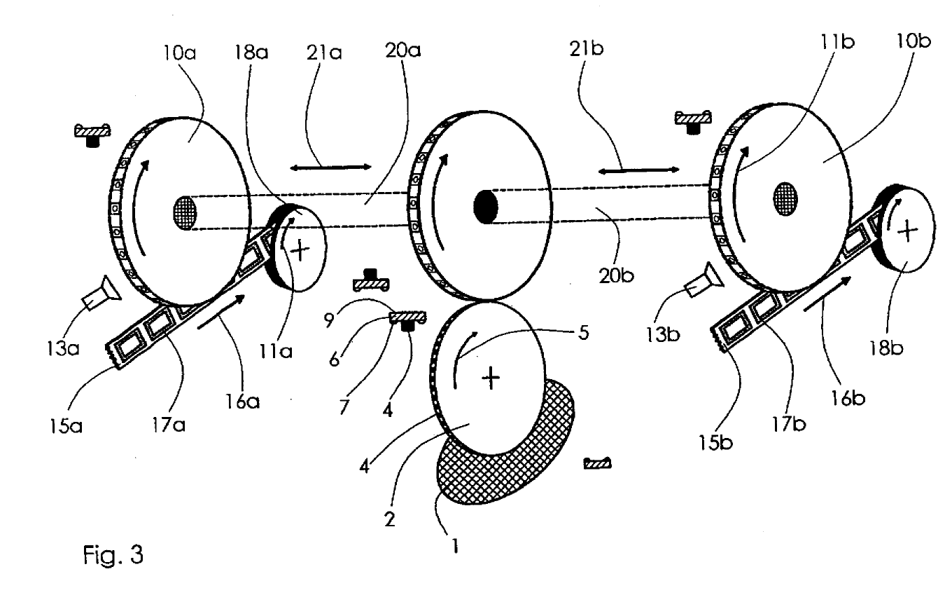

FIG. 3 shows a schematic view of a third embodiment of the apparatus according to the invention; and

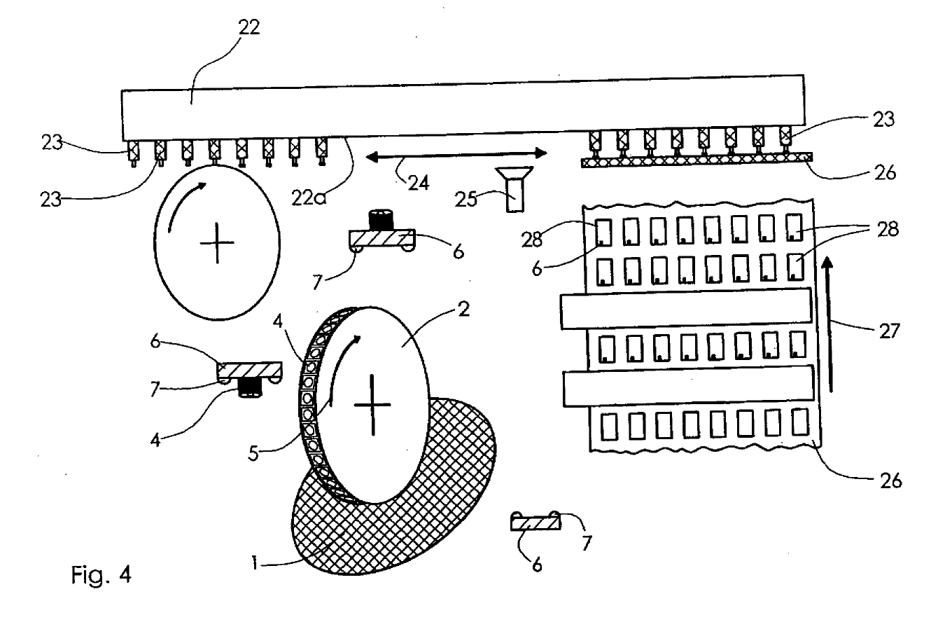

FIG. 4 shows a schematic view of a fourth embodiment of the apparatus according to the invention.

FIG. 1 shows a schematic view of a first embodiment of the apparatus according to the invention. As can be seen in this view, chips 6 are taken from a wafer 1 having a multiplicity of chips disposed thereon by means of a rotating first chip-receiving disc 2 having an outer perimeter 3 and disposed thereon first elements 4 acting with vacuum pressure. The rotational direction of the first disc 3 is indicated by the reference numeral 5. For receiving or picking the individual chips from the wafer, for example any known methods such as an ejector needle for releasing the chips from the substrate film lying thereunder may be used.

The elements 4 acting with vacuum pressure and being very densely disposed on the outer perimeter 3 of the first disc 2, enable the transfer of a large quantity of chips (dice) from the wafer onto the chip-receiving disc 2 due to the rotational movement 5 thereof. In this process, the chips 6 will be kept disposed on the chip contact surfaces 7 disposed on a first surface 8 of the chip, as shown in the enlarged depiction of the chip on the left hand side of the first disc 2 in its position on the outer perimeter 3 of the first disc 2.

Simultaneously with the removal of the individual chips from the wafer 1, individual chips 6 are transferred from the opposite side of the first disc 2 onto a second disc 10 in such a way that the chips 6 are now no longer retained by their first surface 8, but by their second surface 9 by means of second elements 14 acting with vacuum pressure, which are disposed on the outer perimeter 12 of the second disc 10. The rotational movement of the second disc 10 is indicated by the arrow 11. Exact matching of the running speeds of both disks 2, 10 should be ensured in such a manner that an exact reception of the individual chips 6 by means of the elements 14 acting with vacuum pressure may be achieved in order to avoid any damage to the contact surfaces 7.

This flip process of the individual chips, achieved by the cooperation of the two disks 2, 10, may be used to transfer, in a quick and simple manner by means of a rotational movement of both disks, the individual chips 6 from the wafer 1 onto a web 15 which preferably continuously, but possible also discontinuously, moves in the direction 16.

Individual antennae 17 are disposed on the web 15. Once the loading process is completed, the web 15 is wound up by transfer of the chips provided on the outer perimeter 12 of the second disc 10 onto the web on a disc 18 provided therefor, which rotates along the arrow 19. In this case, the chips will be in a position on the outer perimeter of the second disc 10 at the point of transfer onto the web 15, which enables the second elements 14 to engage the second surface 9 of the chip. This enables a mechanical and conductive connection of the contact surfaces 7 of the chip and of the contact surfaces of the antennae 17 (not shown in detail here) by simply pressing the chips 6 onto the antenna contact surfaces. This is done by shifting and pressurizing the second elements 14 acting with vacuum pressure in a radial direction of the disc 10.

Synchronisation between the alignment of the individual chip contact surfaces 7 and the contact surfaces (bond pads) of the antennae (not shown in detail herein) is achieved by means of optical sensors and a position correction of the second elements acting with vacuum pressure and an adjustment of the rotational speed of the flip-chip pressure disc 10. To this end, the optical sensors are disposed in a chip inspection device 13 for measuring the chip position. In this process, the track speed of the web or the belt may be kept constant or may be adjusted.

As an alternative to a continuously moving belt, a discontinuously moving belt may be used for controlling position synchronisation, so that the chips are loaded in a stop-and-go process.

The highest possible throughput rate of the apparatus according to the invention, which means the highest possible speed of the chip mounting process, is achieved when the two disks 2, 10 rotate continuously without being stopped. Alternatively, the disks may be rotated discontinuously, which means they are alternately stopped and moved.

It is contemplated to parallelise the method described in this figure and the process associated therewith in order to increase the throughput rate of the entire apparatus, by taking the chips from the wafer by means of several chip-receiving disks provided in parallel next to each other. Also, several second disks 10 may take over the chips picked up from the first disks and simultaneously place chips on several tracks on a wide web loaded with antennae.

FIG. 2 shows a schematic view of a second embodiment of the apparatus according to the invention. This embodiment shown in FIG. 2 differs from the embodiment shown in FIG. 1 in that the second disc 10 is shifted along an axis 20 identified with the reference numeral 21. By this means, the second disc 10 is fed towards a locally spaced loading axis, on which the web 15 is provided, where chip inspection, including measuring of the chip position, is carried out by means of the device 13 at the location of the loading axis. Here again, the individual chip positions are shown in separate enlarged views in relation to the first and second elements 4, 14 acting with vacuum pressure.

FIG. 3 shows a schematic view of a third embodiment of the apparatus according to the invention. This embodiment differs from the embodiment shown in FIG. 2 in that not only one but two or more second disks 10, 10a, 10b are used, in order to be shifted alternately towards the first disc 2 for receiving the chips, as indicated by the arrows 21a and 21b. The axes 20a and 20b are used for this purpose. In this way it becomes possible that, once the chip positions have been measured using the device 13a and 13b, two antenna webs 15a and 15b may be loaded almost simultaneously. This enhances the throughput rate, since the antenna webs 17a and 17b are allocated to the two or more second disks 10a and 10b working separately from each other.

Also, there are two or more wind-up disks 18a and 18b for the web. The webs as substrate material will, preferably continuously, be moved along the direction of the arrows 16a and 16b. Thus, for example the time interval during which the second disc 10a deposits or presses the chips onto the antennae 17a, may be used to load the second disc 10b with chips 6 currently present on the first disc 2.

FIG. 4 shows a fourth embodiment of the apparatus according to the invention. Where the reference numerals used in this figure correspond to the reference numerals used in the remaining figures, the components are the same or similar.

Again, the chips are picked up from the chip-receiving disc 2 in a position shown in an enlarged view on the left hand side of the disk, and are transferred subsequently onto third elements 23 acting with vacuum pressure, which are provided on a linear, beam-shaped element 23 on a surface 22a. In order to depict the transfer process, the first disc 2 is shown again schematically below the third element 23 acting with vacuum pressure, which is here one and the same disc 2.

The third elements 23 acting with vacuum pressure hold each chip on the second surface 9 which lies opposite the surface 8 including the chip contact surfaces 7. By this means, a flip process of the individual chips 6 has already occurred, without a further second disc having to be used. Subsequently, the third elements are shifted along the direction of the arrow 24, in order to obtain thereby a position opposite a web 26 loaded with antennae on several tracks.

A chip inspection device 25 in turn monitors the positioning and the measuring of the chip alignment. If necessary, the individual third elements 23 acting with vacuum pressure will be aligned by rotating them about an axis vertically to the linear element 22, after that they are moved by means of a pressurised lateral movement downwards to the web shown here in a top view in a transferred manner, in order to deposit the chips thereon and to align them thereto.

The antennae 28 are thus—provided the elements 23 are pressed on at the same time—loaded simultaneously with the chips 6 within one row and the web 26 will subsequently be advanced by one row according to the direction of the arrow 27. This enables parallel loading of 1 . . . n rows.

Again, in order to increase the throughput rate of the entire mechanism, the operation shown herein may be parallelised by means of an apparatus arranged in parallel within a chip mounting system.

The chips are deposited on the web 26 either sequentially, i.e. one after another, or in parallel.

Such a linear element is also referred to as flip-chip pressure axis. Such flip-chip axes may be used for the simultaneous or successive loading of several rows on the antenna web 26.

All of the features disclosed in the application documents are claimed as essential to the invention, provided they are novel either individually or in combination over the prior art.

1. Apparatus for transferring a plurality of chips (6) from a wafer (1) onto a substrate, in particular a web (15),
characterised by
at least one first disc (2) or at least one first roll for successively receiving the chips (6) on its outer perimeter (3) by means of a rotational movement (5) of the first disc or the first roll.

2. Apparatus according to claim 1,
characterised by
at least one second disc (10) or at least one second roll which successively receives on its outer perimeter (12) the chips (6) provided on the outer perimeter (3) of the first disc (2)/the first roll by means of a rotational movement (11) and retains them on a second surface (9) opposite a first surface (8) having contact surfaces (7) turned by 180°.

3. Apparatus according to claim 2,
characterised in that
the chips (6) may be deposited successively on the web (15) by means of the second disc (10) or the second roll by means of a continuous depositing operation.

4. Apparatus according to claim 3,
characterised in that
the second disc (10)/the second roll may be axially shifted prior to the deposition of the chips (6) on the web (15).

5. Apparatus according to any one of claims 2-4,
characterised in that
two second disks (10a, 10b)/two second rolls may be shifted on the left hand side and the right hand side opposite the radial plane of the first disc (2)/the first roll.

6. Apparatus according to any one of claims 2-5,
characterised in that
each chip (6) may be fixed to the first disc (2)/the first roll on the first surface (8) thereof by means of a first element (4) acting with vacuum pressure.

7. Apparatus according to any one of claims 2-6,
characterised in that
each chip (6) may be fixed to the second disc (10)/the second roll on the second surface (9) thereof by means of a second element (14; 14a; 14b) acting with vacuum pressure, respectively.

8. Apparatus according to claim 6 or 7,
characterised in that
the second elements (14; 14a; 14b) acting with vacuum pressure may be shifted and, if necessary, pressurised in the radial direction of the disc (10)/the roll.

9. Apparatus according to any one of claims 6-8,
characterised in that
the elements (14; 14a; 14b) acting with vacuum pressure are supported to rotate about an axis extending in the radial direction of the disc (10)/roll.

10. Apparatus according to claim 1,
characterised by
at least one linear element (22) which [sic] on its surface (22a) with a plurality of third elements (23) disposed in rows and acting with vacuum pressure for successively receiving the chips (6) disposed on the outer perimeter (3) of the first disc (2)/the first roll on its second surface (9) by means of a shifting movement (24) in the longitudinal direction of the linear element (22).

11. Apparatus according to claim 10,
characterised in that
the chips may be deposited successively or simultaneously on the web (26) by means of the linear element (22).

12. Apparatus according to claim 10 or 11,
characterised in that
the third elements (23) acting with vacuum pressure may be shifted vertically to the longitudinal direction of the linear element (22) and may, if necessary, be pressurised.

13. Apparatus according to any one of claims 10-12,
characterised in that
the third elements (23) acting with vacuum pressure are supported to rotate about an axis extending vertically to the longitudinal direction of the linear element (22).

14. Method for transferring a plurality of flip-chips (6) from a wafer (1) onto a substrate, in particular a web (15),
characterised in that
the chips (6) are successively received by at least one first disc (2) or at least one first roll on its outer perimeter (3) by means of a rotational movement (5) of the disc (2)/the roll.

15. Method according to claim 14,
characterised in that
the chips (6) are transferred from the first disc (2)/the first roll onto an outer perimeter (12) of at least one second disc (10)/at least one second roll.

16. Method according to claim 15,
characterised in that
the second disc (10)/the second roll is axially shifted (21) upon transfer of the chips (6).

17. Method according to claim 15,
characterised in that
two second disks (10a, 10b)/two second rolls are axially shifted (21a, 21b) upon transfer of the chips (6) in the opposite direction.

18. Method according to claim 14,
characterised in that
the chips (6) are transferred from the first disc (2)/the first roll onto a linear surface (22a) of a linear element (22).

19. Method according to any one of claims 14-16,
characterised in that
the chips (6) are retained on the outer perimeter (3) of the first disc (2)/of the first roll by means of first elements (4) acting with vacuum pressure by their first surfaces (8) and are retained on the outer perimeter (12) of the second disks (10) (disks (10a, 10b)) of the second roll(s) by means of second elements (14; 14a; 14b) acting with vacuum pressure as well as on the linear surface (22a) of the linear element (22) by means of third elements (23) acting with vacuum pressure by their second surfaces (9).

20. Method according to claim 19,
characterised in that
the elements (4; 14; 14a; 14b; 23) acting with vacuum pressure contact the chips (6) in the contact-free area of the surfaces (8, 9) of the chips (6).

21. Method according to any one of claims 14-20,
characterised in that
the web (15; 15a; 15b) is moved continuously during the transfer of the chips (6) from the second disc (10; 10a; 10b)/from the second roll or from the linear element (22) onto the web (15; 15a; 15b; 26) or is stopped for a short time.
